(19) United States
(12) Patent Application Publication
(10) Pub. No.: US 2011/0156258 A1
(43) Pub. Date: Jun. 30, 2011

(54) SEMICONDUCTOR DEVICE HAVING THROUGH VIA AND METHOD FOR FABRICATING THE SAME

(75) Inventor: Il Cheol RHO, Icheon-si (KR)

(73) Assignee: HYNIX SEMICONDUCTOR INC., Icheon-si (KR)

(21) Appl. No.: 12/978,943

(22) Filed: Dec. 27, 2010

(30) Foreign Application Priority Data
Dec. 29, 2009 (KR) 10-2009-0133245

(51) Int. Cl. H01L 23/48; H01L 21/283

(52) U.S. Cl. 257/751; 438/653; 257/E23.011; 257/E21.159

(57) ABSTRACT

In one embodiment, a semiconductor device may includes a through via disposed within a substrate with a diffusion barrier layer disposed over the through via and the substrate. An insulation layer may be disposed over the diffusion barrier layer, a metal interconnection layer disposed within the insulation layer over at least a portion of the via contact, and a via contact disposed between the metal interconnection layer and the through via within the insulation layer. The via contact may have a cross-sectional area larger than a cross-sectional area of the through via so that the through via and the diffusion barrier layer do not contact each other.

### CROSS-REFERENCES TO RELATED APPLICATIONS

The present application claims priority under 35 U.S.C 119(a) to Korean application number 10-2009-0133245, filed on Dec. 29, 2009, in the Korean intellectual property Office, which is incorporated herein by reference in its entirety.

### BACKGROUND

Exemplary embodiments of the present invention relate to a semiconductor device, and more particularly, to a semiconductor device having a through via (TV) and a method for fabricating the same.

As the demand for compact, highly functional, and portable electronic devices rapidly increases, the reduction in the sizes of the existing two-dimensional horizontal-type chips reaches a limit due to the increase of signal delay in electrical interconnections. To solve this problem, three-dimensional chip stacking technology has recently been widely used to minimize signal delay by vertically stacking chips and replacing long horizontal signal interconnections with short vertical interconnections. A variety of process techniques are required to fabricate three-dimensional chips. A representative technique is a through via technique which electrically couples the vertically stacked wafers or chips by through vias.

FIG. 1 is a cross-sectional view illustrating a typical semiconductor device having a through via. Referring to FIG. 1, through vias 104 are disposed within a substrate 102 such as a silicon substrate. Although FIG. 1 shows that the through vias 104 are embedded within the substrate 102, the substrate 102 may be partially removed in a subsequent process so that the through vias 104 are exposed. As one example, the through vias 104 include a copper (Cu) film. An insulation layer 106 is disposed over the through vias 104 and the substrate 102, and via contacts 108 and 110 and metal interconnection layers 112 and 114 are disposed within the insulation layer 106. The lowermost via contacts 108 are disposed to be coupled to the via holes 104, and a passivation layer 116 is disposed over the uppermost metal interconnection layers 114. A diffusion barrier layer 118 is disposed between the through vias 104 and the insulation layer 106. The diffusion barrier layer 118 substantially prevents metal components of the through vias 104, for example, copper atoms or copper ions, from being diffused into other semiconductor chips. Typically, the diffusion barrier layer 118 includes a nitride film.

When the diffusion barrier layer 118 is formed using a nitride film, a process temperature during the deposition of the nitride film is approximately 400° C. However, it has been known that copper (Cu) constituting the through vias 104 expands at that temperature. Consequently, due to the expansion and contraction of the copper (Cu) during a subsequent process, two films are separated in a region where the through vias 104 and the diffusion barrier layer 118 are contacted with each other, as indicated by reference symbol “A”. In addition, due to great stress between the through vias 104 and the diffusion barrier layer 118, cracks may occur in the diffusion barrier layer 118. Such cracks may propagate to the metal interconnection layers 112 and 114, causing significant degradation in the stability of the device.

### SUMMARY

Various embodiments of the invention may describe a first layer as being “over” or “on” a second layer. These terms may mean that the first layer is directly on top of the second layer, or that there may be at least one other layer between the first layer and the second layer.

An embodiment of the present invention relates to a semiconductor device which is capable of suppressing the separation of a through via and a diffusion barrier layer or the occurrence of cracks within the diffusion barrier layer.

Another embodiment of the present invention relates to a method for fabricating the semiconductor device having the through via.

In one embodiment, a semiconductor device includes: a substrate; a through via disposed within the substrate; a diffusion barrier layer disposed over the through via and the substrate; an insulation layer disposed over the diffusion barrier layer; a metal interconnection layer disposed within the insulation layer over at least a portion of the via contact; and a via contact disposed between the metal interconnection layer and the through via within the insulation layer and having a cross-sectional area larger than a cross-sectional area of the through via so that the through via and the diffusion barrier layer do not contact each other.

The through via may include a copper film, and the diffusion barrier layer may include a nitride film.

In another embodiment, a method for fabricating a semiconductor device includes: forming holes for through vias within a substrate; depositing a metal film to fill the holes; forming mutually isolated through vias by performing a planarization process on the metal film to expose the surface of the substrate; forming a diffusion barrier layer over the through vias and the substrate; forming an insulation layer over the diffusion barrier layer; forming via contact holes exposing the surfaces of the through vias and the surface of the substrate surrounding the through vias by partially removing, or proportionally removing portions of, the insulation layer and the diffusion barrier layer; and forming via contacts by filling the via contact holes with a conductive film, the via contact having a cross-sectional area larger than a cross-sectional area of the through via.

The through via may include a copper film, and the diffusion barrier layer may include a nitride film.

After the planarization process, the method may further include performing an annealing process on the through vias before the diffusion barrier layer is formed.

An annealing process may be performed on the through via before the diffusion barrier layer is formed, where the annealing process temperature may, for example, at least equal a process temperature used in the formation of the diffusion barrier layer. An embodiment of the invention may have the annealing process temperature be in the range of, for example, approximately 400° C. to approximately 500° C.

In another embodiment, a method for fabricating a semiconductor device includes: forming holes for through vias within a substrate; depositing a metal film to fill the holes; forming mutually isolated through vias by performing a planarization process on the metal film to expose the surface of the substrate; performing an annealing process on the mutually insulated through vias; forming a diffusion barrier layer over the through vias and the substrate after the annealing process is performed; forming an insulation layer over the diffusion barrier layer; forming via contact holes exposing the surfaces of the through vias and the surface of the substrate surrounding the through vias by partially removing the insulation layer and the diffusion barrier layer; and forming via contacts by filling the via contact holes with a conductive film.

The annealing process on the mutually insulated through vias may be performed at a temperature higher than a process temperature upon the formation of the diffusion barrier layer.

The through vias may include a copper film, and the diffusion barrier layer may include a nitride film.

When the through vias are formed using the copper film, the annealing process on the through vias may be performed at a temperature at least equal to a process temperature used in the formation of the diffusion barrier layer. An embodiment of the invention may have the annealing process temperature be in the range of, for example, approximately 400° C. to approximately 500° C.

### BRIEF DESCRIPTION OF THE DRAWINGS

The above and other aspects, features and other advantages will be more clearly understood from the following detailed description taken in conjunction with the accompanying drawings, in which:

FIG. 1 is a cross-sectional view illustrating a typical semiconductor device having a through via;

FIG. 2 is a cross-sectional view illustrating a semiconductor device having a through via according to an embodiment of the present invention;

FIGS. 3 to 6 are cross-sectional views illustrating a method for fabricating a semiconductor device having a through via according to an embodiment of the present invention; and

FIGS. 7 to 11 are cross-sectional views illustrating a method for fabricating a semiconductor device having a through via according to an embodiment of the present invention.

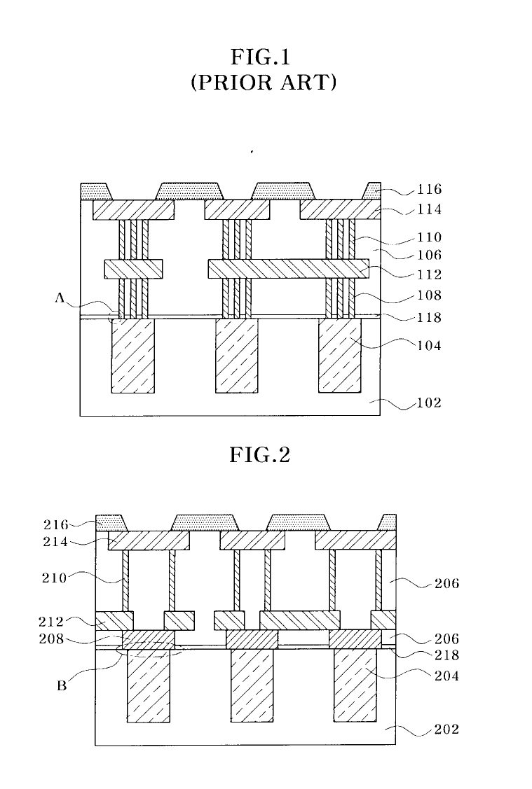

### DESCRIPTION OF SPECIFIC EMBODIMENTS

Hereinafter, embodiments of the present invention will be described with reference to accompanying drawings. However, the embodiments are for illustrative purposes only and are not intended to limit the scope of the invention.

FIG. 2 is a cross-sectional view illustrating a semiconductor device having a through via according to an embodiment of the present invention. Referring to FIG. 2, through vias 204 are disposed within a substrate 202 such as, for example, a silicon substrate. Although FIG. 2 shows that the through vias 204 are embedded within the substrate 202, the substrate 202 may be partially removed in a subsequent process so that the through vias 204 are exposed. As one example, the through vias 104 may include, for example, a copper (Cu) film (not shown). First via contacts 208 are disposed over the through vias 204, and a diffusion barrier layer 218 is disposed over the substrate 202 around the first through contacts 208. The diffusion barrier layer 218 prevents metal components of the through vias 204, for example, copper atoms or copper ions, from being diffused into other semiconductor chips. As one example, the diffusion barrier layer 118 may include a nitride film.

As indicated by reference symbol “B”, a surface cross-sectional area of the first via contact 208 contacting the through via 204 is larger than that of the through via 204. That is, the entire top surface of the through via 204 contacts the first via contact 208 and thus does not overlap the diffusion barrier layer 218. Therefore, the through via 204 and the diffusion barrier layer 218 may not be separated from each other by the expansion and contraction of the copper film, constituting the through via 204, in an annealing process.

A first metal interconnection layer 212 is disposed over the first via contact 208. Thus, the through via 204 and the first metal interconnection layer 212 are electrically coupled together by the first via contact 208. A second metal interconnection layer 214 is disposed over the first metal interconnection layer 212. The first metal interconnection layer 212 and the second metal interconnection layer 214 are electrically coupled together by second via contacts 210. The first via contacts 208, the first metal interconnection layer 212, the second via contacts 210, and the second metal interconnection layer 214 are surrounded by an insulation layer 206. Although the insulation layer 206 having a monolayer structure is illustrated in FIG. 2, the insulation layer 206 may have a multilayer structure. A passivation layer 216 is disposed over the second metal interconnection layer 214.

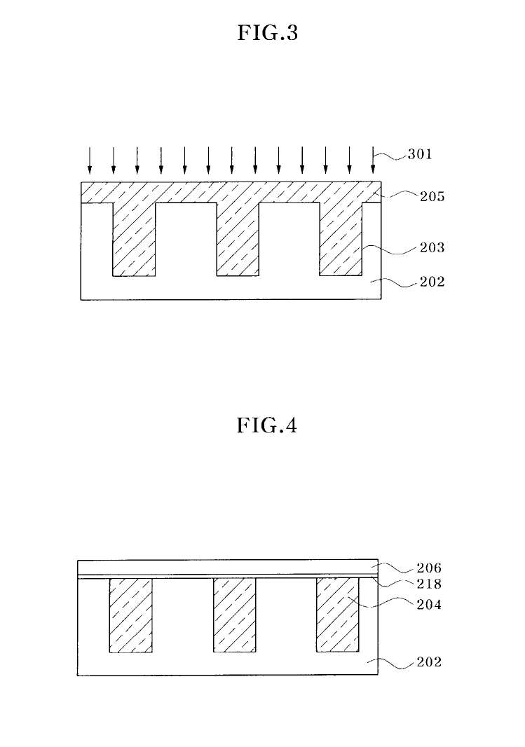

FIGS. 3 to 6 are cross-sectional views illustrating a method for fabricating a semiconductor device having a through via according to an embodiment of the present invention. Referring to FIG. 3, holes 203 for through vias are formed in a substrate 202 such as, for example, a silicon substrate. Although not illustrated, a barrier metal layer (for example, a tantalum (Ta) film) is formed, and a metal seed (for example, a copper (Cu) seed) is deposited. The copper (Cu) seed may be deposited by using a sputtering process. Next, using the copper (Cu) seed, a copper (Cu) film 205 is deposited to fill the holes 203. The copper (Cu) film 205 may be deposited, for example, by an electroplating process. As indicated by arrows 301, an annealing process is performed on the copper (Cu) film 205 to thereby improve characteristics of the copper (Cu) film 205. The annealing process is performed at a temperature of approximately 400° C.-500° C.

Referring to FIG. 4, through vias 204 are formed to be embedded within the substrate 202 by performing a planarization process on the copper (Cu) film 205. Accordingly, the through vias 204 are arranged to be isolated from adjacent through vias. The planarization process may be performed by using a chemical mechanical polishing (CMP) process. Then, a diffusion barrier layer 218 is formed over the substrate 202 and the through vias 204, and an insulation layer 206 is formed over the diffusion barrier layer 218. The diffusion barrier layer 218 may be formed by depositing a nitride film at a process temperature of approximately 400° C.

In this embodiment, although not illustrated, after forming the through vias 204, an annealing process may be performed on the through vias 204 before forming the diffusion barrier layer 218. This annealing process is performed at a process temperature equal to or higher than the process temperature upon the deposition of the diffusion barrier layer 218. For example, when a nitride film deposited at a process temperature of approximately 400° C. is used as the diffusion barrier layer 218, an annealing process is performed at a temperature of approximately 400° C. to approximately 500° C. As such, the through vias 204 expand because the annealing process is performed prior to the deposition of the diffusion barrier layer 218 at a temperature equal to or higher than the process temperature upon the deposition of the diffusion barrier layer 218, and then, the through vias 204 again contract when the annealing process is completed and the temperature drops. At this time, the contraction does not occur to a room temperature level, but partially occurs in an elastic portion. Therefore, although the through vias 204 expand due to the process temperature during the subsequent process of forming the diffusion barrier layer 218, the entire through via 204 does not expand, but only the elastic portion that contracted may expand. Furthermore, even though the contraction occurs after the diffusion barrier layer 218 is formed, the degree of the contraction is slight.

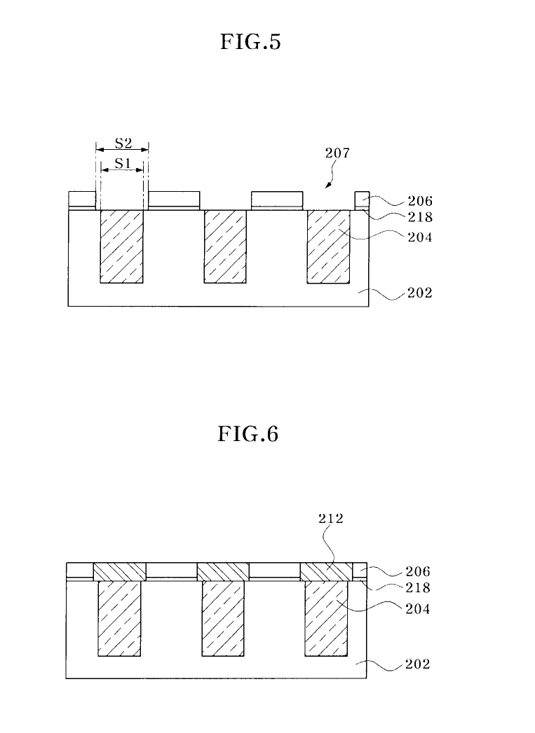

Referring to FIG. 5, via contact holes 207 exposing the top surfaces of the through vias 204 are formed by partially removing the insulation layer 206 and the diffusion barrier layer 218. In this case, the via contact hole 207 is formed to have a cross-sectional area S2 larger than a cross-sectional area S1 of the top exposed surface of the through via 204. Accordingly, the top surfaces of the through vias 204 and the partial surface of the substrate 202 surrounding the through vias 204 are exposed through the via contact holes 207.

Referring to FIG. 6, a conductive film may be deposited to fill the via contact holes 207 (FIG. 5), and first via contacts 208 may be formed by performing a planarization process until the surface of the insulation layer 206 is exposed. As described above with reference to FIG. 5, since the cross-sectional area of the via contact hole 207 is larger than the cross-sectional area of the top surface of the through via 204, the cross-sectional area of the bottom surface of the first via contact 208 contacting the through via 204 is larger than the cross-sectional area of the top surface of the through via 204. As a result, the through via 204 and the diffusion barrier layer 218 do not contact each other. After forming the first via contacts 208, a first metal interconnection layer 212, second via contacts 210, a second metal interconnection layer 214, an insulation layer 206, and a passivation layer 216 are formed by typical processes, as illustrated in FIG. 2.

FIGS. 7 to 11 are cross-sectional views illustrating a method for fabricating a semiconductor device having a through via according to an embodiment of the present invention. Referring to FIG. 7, holes 303 for through vias are formed in a substrate 302 such as, for example, a silicon substrate. Although not illustrated, a barrier metal layer (for example, a tantalum (Ta) film) is formed, and a metal seed (for example, a copper (Cu) seed) is deposited. The copper (Cu) seed may be deposited by using a sputtering process. Next, using the copper (Cu) seed, a copper (Cu) film 305 is deposited to fill the holes 303. The copper (Cu) film 305 may be deposited by an electroplating process.

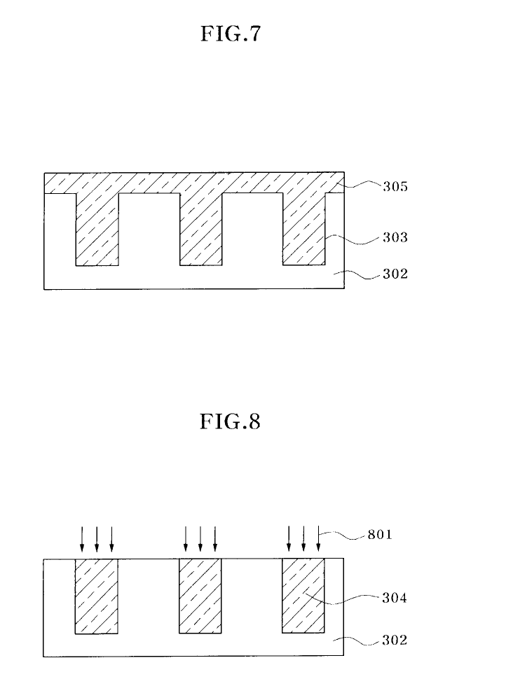

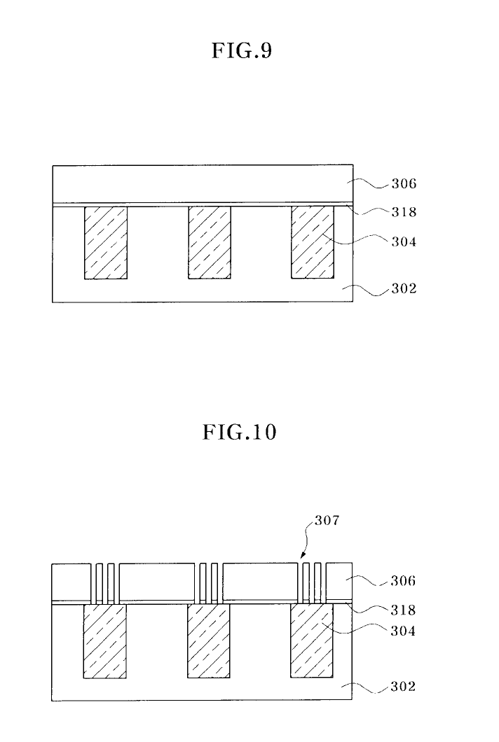

Referring to FIG. 8, through vias 304 are formed to be embedded within the substrate 302 by performing a planarization process on the copper (Cu) film 305. Accordingly, the through vias 304 are arranged to be isolated from other adjacent through vias 304. The planarization process may be performed by using a chemical mechanical polishing (CMP) process. Then, as indicated by arrows 801, an annealing process is performed on the through vias 304. The annealing process is performed at a temperature equal to or higher than the process temperature upon the subsequent deposition of a diffusion barrier layer. For example, when a nitride film deposited at a process temperature of approximately 400° C. is used as the diffusion barrier layer, an annealing process may be performed at a temperature of approximately 400° C. to approximately 500° C. As such, the through vias 304 expand because the annealing process is performed prior to the deposition of the diffusion barrier layer at a temperature equal to or higher than the process temperature upon the deposition of the diffusion barrier layer, and then, the through vias 304 again contract when the annealing process is completed and the temperature drops. At this time, the contraction does not occur to a room temperature level, but partially occurs in an elastic portion. Therefore, although the through via 304 expands due to the process temperature during the subsequent process of forming the diffusion barrier layer 318, the entire through via 304 does not expand, but only the elastic portion having contracted may expand. Furthermore, even though the contraction occurs after the diffusion barrier layer 318 (see FIG. 9) is formed, the degree of the contraction may be slight.

Referring to FIG. 9, the diffusion barrier layer 318 is formed over the substrate 302 and the through vias 304, and an insulation layer 306 is formed over the diffusion barrier layer 318. The diffusion barrier layer 318 may be formed by depositing a nitride film at a process temperature of approximately 400° C. As the diffusion barrier layer 318 is formed by depositing a nitride film at a process temperature of approximately 400° C., the copper (Cu) film constituting the through via 304 may expand and contract. However, the entire through via 304 does not expand, but only the elastic portion having contracted may expand. Furthermore, even though the contraction occurs, the degree of the contraction may be slight. As a result, the separation between the through via 304 and the subsequent diffusion barrier layer 318 may be reduced, if not eliminated.

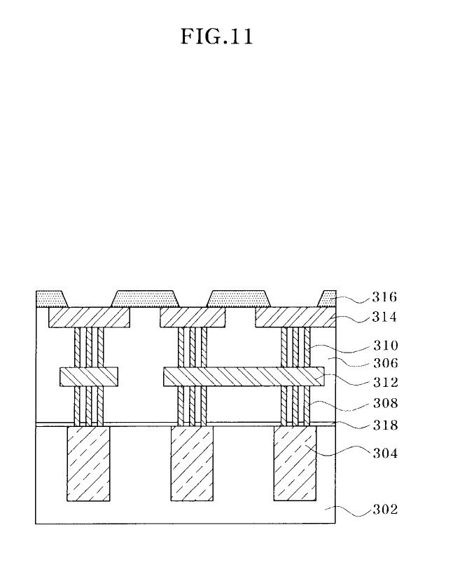

Referring to FIGS. 10 and 11, via contact holes 307 exposing the top surfaces of the through vias 304 are formed by partially removing the insulation layer 306 and the diffusion barrier layer 318. A conductive film is deposited to fill the via contact holes 307, and first via contacts 308 are formed by performing a planarization process until the surface of the insulation layer 306 is exposed. After forming the first via contacts 312, a first metal interconnection layer 308, second via contacts 310, a second metal interconnection layer 314, an insulation layer 306, and a passivation layer 316 are formed by typical processes.

According to the embodiments of the present invention, since the cross-sectional area of the via contact coupling the metal interconnection layer and the through via is larger than the cross-sectional area of the through via, the through via and the metal interconnection layer do not contact each other. As a result, it may be possible to reduce, if not eliminate the separation between the through via and the diffusion barrier layer, which is caused by the expansion and contraction of the through via during the formation of the diffusion barrier layer. Furthermore, the planarization process is performed for the formation of the through via, and the annealing process is performed on the through via before the formation of the diffusion barrier layer. Thus, the degree of the expansion and contraction of the through via due to the temperature upon the subsequent formation of the diffusion barrier layer can be reduced. Accordingly, the separation between the through via and the diffusion barrier layer may be reduced, if not eliminated.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed:

1. A semiconductor device comprising:
a through via disposed within a substrate;
a via contact, surrounded at least in part by a diffusion barrier layer, wherein the diffusion barrier layer is disposed over the through via and at least a portion of the substrate, within an insulation layer, and having a cross-sectional area larger than a cross-sectional area of the through via so that the through via and the diffusion barrier layer do not contact each other.

2. The semiconductor device of claim 1, wherein the through via comprises a copper film.

3. The semiconductor device of claim 1, wherein the diffusion barrier layer comprises a nitride film.

4. The semiconductor device of claim 1, wherein the insulation layer is disposed over the diffusion barrier layer.

5. The semiconductor device of claim 4, further comprising a metal interconnection layer disposed within the insulation layer.

6. A method comprising:
forming through via within a substrate;
forming a diffusion barrier layer over the substrate and the through via;
forming an insulation layer over the diffusion barrier layer;
removing proportional portions of the diffusion barrier layer and the insulation layer; and
forming a via contact over the through via in the proportional portions removed such that the via contact makes contact with the through via, wherein the via contact has a cross-sectional area larger than a cross-sectional area of the through via such that the through via and the diffusion barrier layer do not contact each other.

7. The method of claim 6, wherein the through via comprises a copper film.

8. The method of claim 6, wherein the diffusion barrier layer comprises a nitride film.

9. The method of claim 6, further comprising a metal interconnection layer disposed over at least a portion of the via contact.

10. The method of claim 6, further comprising performing an annealing process on the through via before the diffusion barrier layer is formed.

11. The method of claim 10, wherein the annealing process is performed at a temperature at least equal to a process temperature used in the formation of the diffusion barrier layer.

12. The method of claim 10, wherein the annealing process on the through via is performed at a temperature of approximately 400° C. to approximately 500° C.

13. A method for fabricating a semiconductor device, the method comprising:
forming holes for through vias within a substrate;
depositing a metal film to fill the holes;
forming mutually isolated through vias by performing a planarization process on the metal film to expose the surface of the substrate;
performing an annealing process on the mutually insulated through vias;
forming a diffusion barrier layer over the through vias and the substrate after the annealing process is performed;
forming an insulation layer over the diffusion barrier layer;
forming via contact holes exposing the surfaces of the through vias and the surface of the substrate surrounding the through vias by partially removing the insulation layer and the diffusion barrier layer; and
forming via contacts by filling the via contact holes with a conductive film.

14. The method of claim 13, wherein the annealing process on the mutually insulated through vias is performed at a temperature higher than a process temperature upon the formation of the diffusion barrier layer.

15. The method of claim 13, wherein the metal film is deposited using an electroplating process.

16. The method of claim 13, wherein the through vias comprise a copper film.

17. The method of claim 16, comprising depositing copper seed in the holes prior to depositing the copper film.

18. The method of claim 17, wherein the copper seed is deposited using a sputtering process.

19. The method of claim 13, wherein the diffusion barrier layer comprises a nitride film.

20. The method of claim 13, wherein the annealing process on the through vias is performed at a temperature of approximately 400° C. to approximately 500° C.

21. The method of claim 13, wherein the annealing process on the through vias is performed at a temperature at least equal to a process temperature used in the formation of the diffusion barrier layer.
